(19) United States
(12) Patent Application Publication
(10) Pub. No.: US 2022/0165577 A1
(43) Pub. Date: May 26, 2022

(54) ELEMENT CHIP MANUFACTURING METHOD AND PLASMA PROCESSING METHOD

(71) Applicant: Panasonic Intellectual Property Management Co., Ltd., Osaka (JP)

(72) Inventors: Toshiyuki TAKASAKI, OSAKA (JP); Shogo OKITA, HYOGO (JP); Akihiro ITOU, KYOTO (JP); Atsushi HARIKAI, OSAKA (JP)

(21) Appl. No.: 17/455,678

(22) Filed: Nov. 19, 2021

(30) Foreign Application Priority Data
Nov. 20, 2020 (JP) 2020-193871

(51) Int. Cl. H01L 21/3065; H01L 21/78

(52) U.S. Cl. CPC H01L 21/30655; H01L 21/78

(57) ABSTRACT

A plasma processing method including: exposing to a first plasma a substrate having a compound semiconductor layer and a mask partially covering a surface of the compound semiconductor layer, to form a protective film at least on the bottom of a groove formed in a region where the compound semiconductor layer is not covered with the mask; removing the protective film at the bottom by exposing the substrate to a second plasma, to expose the compound semiconductor layer; and removing the conductive semiconductor layer exposed at the bottom of the groove by exposing the substrate to a third plasma generated from a gas containing chlorine and/or bromine, while allowing a reaction product between the compound semiconductor layer and the third plasma to accumulate on an upper portion of the groove. The reaction product is removed by applying a high-frequency power to a stage on which the substrate is placed.

### CROSS REFERENCE TO RELATED APPLICATION

The present application is based on and claims priority under 35 U.S.C. § 119 with respect to the Japanese Patent Application No. 2020-193871 filed on Nov. 20, 2020, of which entire content is incorporated herein by reference into the present application.

### TECHNICAL FIELD

The present invention relates to a plasma processing method, specifically to a method for dicing a substrate having a compound semiconductor layer.

### BACKGROUND

In the field of dry etching and plasma dicing, a Bosch process in silicon layer etching is known as a cycle etching method for forming a deep groove having a high aspect ratio (ratio of the depth to the width of the groove) in a substrate being a processing subject layer.

In the Bosch process, a protective film deposition step, a protective film removal step of removing the protective film deposited on the bottom of the groove, and a processing subject layer etching step are repeated in this order (see, e.g., Japanese Laid-Open Patent Publication 2014-45160). Through this process, a protective film is formed on the sidewall of the groove, and the processing subject layer is etched in the depth direction while the etching in the plane direction thereof is suppressed by the protective film. As a result, a groove having a high aspect ratio can be formed in the processing subject layer.

Compound semiconductors, such as GaAs, AlGaAs, AlAs, InP, GaP, CdTe, ZnSe, SiC, and GaN, when etched, produce a product lower in volatility than that silicon and silicon oxide produce. When the above cycle etching method is employed to form a deep groove in a substrate containing these compound semiconductors, a product produced by etching attaches to the sidewall of the groove, to narrow the opening, which as a result, may lead to a reduced processing accuracy and a reduced processing speed.

For example, for etching a GaAs substrate with plasma, a chlorine-based gas is often used as an etching gas. However, when the cycle etching method is performed on a GaAs substrate, and a chlorine-based gas is used in the processing subject layer etching step, a reaction product between the chlorine-based gas and Ga or As, due to its low volatility, may be left without being exhausted outside and attach to the sidewall of the groove, in some cases, which narrows the opening. This may reduce the etching speed and the processing accuracy, resulting in a tapered shape of the processed groove, or causing the etching to fail to proceed.

### SUMMARY

One aspect of the present invention relates to an element chip manufacturing method, including: a preparation process of preparing a substrate having a compound semiconductor layer and a mask, the compound semiconductor layer including a plurality of element regions and a dividing region defining the element regions, the mask covering the compound semiconductor layer in the element regions and exposing the compound semiconductor layer in the dividing region; a placement process of placing the substrate on a stage provided in a processing chamber of a plasma processing apparatus; and an individualization process of forming a groove corresponding to the dividing region in the compound semiconductor layer, with a plasma generated inside the processing chamber, and then dividing the substrate into a plurality of element chips having the element regions, wherein in the individualization process, a first process of forming a protective film at least on a bottom of the groove, with a first plasma generated inside the processing chamber, a second process of removing the protective film at the bottom, with a second plasma generated inside the processing chamber, to expose the compound semiconductor layer, and a third process of removing the conductive semiconductor layer exposed at the bottom of the groove, with a third plasma generated inside the processing chamber from a gas containing at least one of chlorine and bromine, while allowing a reaction product between the compound semiconductor layer and the third plasma to accumulate on an upper portion of the groove are sequentially repeated, and in the first process, the reaction product accumulated on the upper portion of the groove is removed by applying a high-frequency power to the stage.

Another aspect of the present invention relates to A plasma processing method, including: a preparation process of preparing a substrate having a compound semiconductor layer and a mask partially covering a surface of the compound semiconductor layer; a placement process of placing the substrate on a stage provided in a processing chamber of a plasma processing apparatus; and a process of forming a groove in the compound semiconductor layer in a region where the compound semiconductor layer is not covered with the mask, wherein in the process of forming a groove, a first process of forming a protective film at least on a bottom of the groove by exposing the substrate to a first plasma, a second process of removing the protective film at the bottom by exposing the substrate to a second plasma, to expose the compound semiconductor layer, and a third step of removing the compound semiconductor layer exposed at the bottom of the groove by exposing the substrate to a third plasma generated from a gas containing at least one of chlorine and bromine, while allowing a reaction product between the compound semiconductor layer and the third plasma to accumulate on an upper portion of the groove are sequentially repeated, and in the first process, the reaction product accumulated on the upper portion of the groove is removed by applying a high-frequency power to the stage.

According to the present invention, it is possible to easily form a deep groove in a compound semiconductor substrate, and thus to easily obtain individual element chips by plasma dicing.

### BRIEF DESCRIPTION OF THE DRAWINGS

FIG. 1A is a top view schematically showing a conveying carrier holding a substrate and

FIG. 1B is a cross-sectional view thereof along the line BB.

FIG. 2 is a conceptual cross-sectional diagram showing a structure of a plasma processing apparatus.

FIG. 3 is an exemplary flowchart of an element chip manufacturing method (plasma processing method) according to an embodiment of the present invention.

FIG. 4 is another exemplary flowchart of an element chip manufacturing method (plasma processing method) according to an embodiment of the present invention.

FIG. 5 is yet another exemplary flowchart of an element chip manufacturing method (plasma processing method) according to an embodiment of the present invention.

FIG. 6A is an SEM photograph of a cross section of a substrate obtained by forming a deep groove in a GaAs substrate using a plasma processing method according to an embodiment of the present invention.

FIG. 6B is an SEM photograph of a cross section of a substrate obtained by forming a deep groove in a GaAs substrate using a conventional plasma processing method.

### DETAILED DESCRIPTION

One embodiment of the present invention relates to an element chip manufacturing method for dividing a substrate having a compound semiconductor layer, into a plurality of individual element chips. Specifically, the compound semiconductor layer includes a plurality of element regions and a dividing region defining the element regions. The substrate includes a compound semiconductor layer and a mask covering the compound semiconductor layer in the element regions and exposing the compound semiconductor layer in the dividing region. The mask forms an opening in the dividing region.

The element chip manufacturing method includes: a preparation process of preparing the above substrate; a placement process of placing the substrate on a stage provided in a processing chamber of a plasma processing apparatus; and an individualization process of forming a groove in a region corresponding to the dividing region in the compound semiconductor layer, with a plasma generated inside the processing chamber, and then dividing the substrate into a plurality of element chips having the element regions. In the individualization process, the substrate is divided into a plurality of element regions by, for example, dicing, to obtain element chips. In the individualization step, the following processes (i) to (iii) are sequentially repeated as one cycle.

Process (i): Protective Film Formation Process

A protective film is formed at least on the bottom of the groove, with a first plasma generated inside the processing chamber. The protective film acts to inhibit the compound semiconductor layer on the sidewall of the groove from reacting with the plasma and being etched in the step (iii), to prevent the groove from being widened.

Process (ii): Protective Film Removal Process

Next, the protective film is removed at the bottom, with a second plasma generated inside the processing chamber, to expose the compound semiconductor layer.

Process (iii): Compound Semiconductor Layer Removal Process

Subsequently, the compound semiconductor layer exposed at the bottom of the groove is removed, with a third plasma generated inside the processing chamber while a gas containing at least one of chlorine and bromine is supplied thereinto. In this process, the groove is deepened. The gas may contain only one of chlorine and bromine, or may contain both of them.

Etching of the compound semiconductor layer is usually performed by using an etching gas containing chlorine and/or bromine, such as Cl₂ and Br₂. However, a reaction product between such an etching gas and the compound semiconductor is generally low in volatility. Therefore, with the increase in the depth of the groove, a reaction product of the compound semiconductor and the third plasma produced at the bottom of the groove cannot be exhausted outside the groove, and tends to attach to the sidewall of the groove and accumulate thereon. The reaction product is likely to attach to, in particular, an upper portion of the groove (e.g., a sidewall of the mask) and accumulate thereon, tending to narrow the opening of the groove. As a result, the etching speed may be slowed and the processed groove may have a tapered shape. Furthermore, the deposition of the protective film on the sidewall of the groove may be inhibited, and the etching may fail to proceed.

In view of the above, in the method of the present embodiment, a high-frequency power is applied to the stage in the above step (i) (protective film formation step). The application of a high-frequency power produces a self-bias potential between the stage and the plasma, and the ions in the plasma are accelerated by the bias potential toward the substrate placed on the stage and collide therewith. The energy of the collision removes the reaction product having accumulated on the upper portion of the groove and having narrowed the opening. Therefore, in the step (iii), while the sidewall surface is maintained almost vertically and the aspect ratio is maintained high, the groove can be processed deeper. The high-frequency power applied to the stage in the step (i) may be 25 W or more, and may be 50 W or more, or 75 W or more.

The method according to the present disclosure is not limited to the element chip manufacturing use, and can be utilized for forming a deep groove in the compound semiconductor layer of a substrate. In the plasma processing method of the present embodiment, in the preparation step, a substrate in which the surface of the compound semiconductor layer is partially covered with a mask is prepared. An opening is formed in a region where the compound semiconductor layer is not covered with the mask. In this case, too, by sequentially repeating the above steps (i) to (iii) as one cycle with respect to this opening, a groove can be formed in the compound semiconductor layer in a region where the compound semiconductor layer is not covered with the mask, and the groove can be processed into a deep groove having a high aspect ratio.

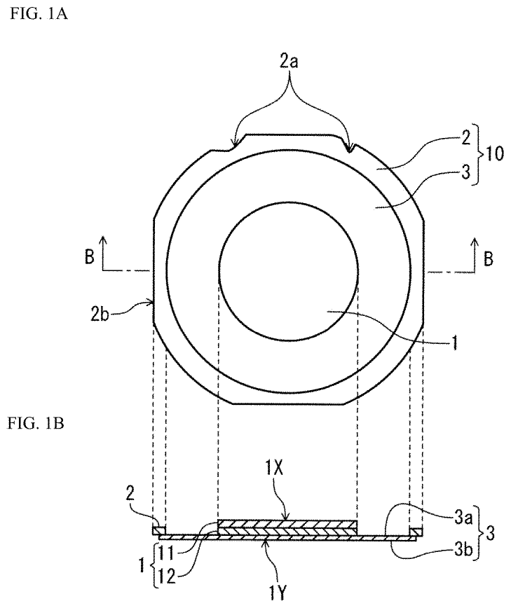

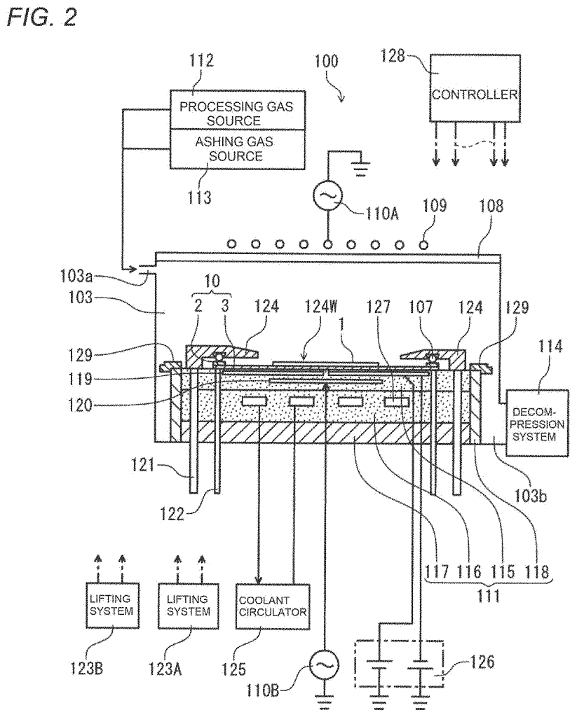

A detailed description will be given below of an element chip manufacturing method (plasma processing method) according to an embodiment of the present invention, with reference to the drawings. FIG. 1A is a top view schematically showing a conveying carrier holding a substrate, and FIG. 1B is a cross-sectional view thereof along the line BB. FIG. 2 is a conceptual diagram showing a structure of a plasma processing apparatus in a cross section. It is to be noted, however, the present invention is not limited by the configurations of the conveying carrier and the plasma processing apparatus.

### (Preparation Process)

First, a substrate 1 to be subjected to dicing is prepared. The substrate 1 has a first principal surface 1X and a second principal surface 1Y, and is zoned into a dividing region (also referred to as a street St) and a plurality of element regions defined by the dividing region (both not shown). By etching the substrate 1 along the street St, the substrate 1 is divided into individual element chips having the element regions. The element regions may have a circuit layer, such as a semiconductor circuit, an electronic component element, or a MEMS.

The substrate 1 includes, for example, a first layer 11 and a second layer 12 which is a semiconductor layer formed on the second principal surface 1Y side of the first layer 11. The first layer functions as a mask in the individualization process, and is patterned so as to cover the second layer (semiconductor layer) in the element regions and expose the second layer (semiconductor layer) in the dividing region. The first layer includes, for example, an electrically insulating film, a metal material, a resin protective layer (e.g., polyimide), a resist layer, an electrode pad, bumps, and the like. The insulating film may be included as a layered body with a metal material for wiring (multilevel wiring layer). The insulating film includes, for example, a resin film (e.g., polyimide), silicon dioxide (SiO₂), silicon nitride (Si₃N₄), a low dielectric film (Low-k film), and the like. The resist layer includes, for example, a resist material, such as a thermosetting resin (e.g., polyimide), a photoresist (e.g., phenol resin), or a water-soluble resist (e.g., acrylic resin). When the first layer is a photoresist, the patterning of the first layer can be performed by, for example, photolithography. When the first layer is an insulating film or a metal material, the first layer can be patterned by, for example, laser scribing or etching. The second layer is a compound semiconductor layer. Examples of the compound semiconductor constituting the compound semiconductor layer include: III-V semiconductors, such as GaAs, AlGaAs, AlAs, InP, GaP, and GaN; II-VI semiconductors, such as CdTe and ZnSe; and IV-IV semiconductors containing a plurality of Group IV elements, such as SiC.

The thickness of the first layer is not limited, and is, for example, 2 to 10 When the first layer includes a secondary wiring layer or bumps, the thickness of the first layer is, for example, up to approximately 200 The thickness of the resist layer is also not limited, and is, for example, 5 to 20 The thickness of the second layer is also not limited, and is, for example, 20 to 1000 and may be 100 to 300 The size of the substrate 1 is also not limited, and is, for example, approximately 50 mm to 300 mm in maximum diameter. The shape of the substrate 1 is also not limited, and is, for example, circular or square. The substrate 1 may be provided with a cutout (not shown), such as an orientation flat or a notch.

Here, in view of the ease of handling, the individualization process described hereinafter is preferably performed, with the second principal surface 1Y of the substrate 1 being supported on a supporting member 3. In this case, in the preparation process, a conveying carrier 10 is prepared together with the substrate 1.

The material of the supporting member 3 is not limited. In particular, given that the substrate 1 is diced while being supported on the supporting member 3, the supporting member 3 is preferably a flexible resin film because in this case the obtained element chips can be easily picked up. Therefore, for ease of handling, the supporting member 3 is secured to a frame 2. Hereinafter, the frame 2 and the supporting member 3 secured to the frame 2 are collectively referred to as the conveying carrier 10.

The material of the resin film is not limited, and may be, for example, a thermoplastic resin, such as polyolefin (e.g., polyethylene, polypropylene), and polyester (e.g., polyethylene terephthalate). The resin material may be blended with a rubber component for adding elasticity (e.g., ethylene-propylene rubber (EPM), ethylene-propylene-diene rubber (EPDM)), and various additives, such as a plasticizer, a softener, an antioxidant, and an electrically conductive material. The above thermoplastic resin may have a functional group that reacts during photopolymerization reaction, such as an acryl group.

The supporting member 3 includes, for example, a surface having an adhesive (adhesive surface 3a) and a surface not having an adhesive (non-adhesive surface 3b). The outer periphery of the adhesive surface 3a is attached to one side of the frame 2, covering the opening of the frame 2. The substrate 1 is attached and held on a portion of the adhesive surface 3a exposed from the opening of the frame 2. In the plasma dicing process, the supporting member 3 is placed on the stage, with the non-adhesive surface 3b in contact with the stage provided in the processing chamber (hereinafter, the vacuum chamber) of a plasma processing apparatus.

The adhesive surface 3a is preferably made of an adhesive component, the adhesive strength of which is reduced by ultraviolet (UV) irradiation. When picking up element chips 20 after plasma dicing, the element chips 20 can be easily peeled off from the adhesive surface 3a by UV irradiation, which eases the pickup. The supporting member 3 can be obtained by, for example, applying a UV curing acrylic adhesive on one side of a resin film, in a thickness of 5 to 20 μm.

The frame 2 is a frame member having an opening equal to or greater in area than the whole substrate 1, and has a predetermined width and a substantially constant thin thickness. The frame 2 has such a rigidity that it can be conveyed with the supporting member 3 and the substrate 1 held thereon. The shape of the opening of the frame 2 is not limited, and may be, for example, circular, or polygonal, such as rectangular or hexagonal. The frame 2 may be provided with a notch 2a for positioning and/or a corner cut 2b. The material of the frame 2 may be, for example, a metal, such as aluminum or stainless steel, a resin, and the like.

The conveying carrier 10 can be obtained by attaching the supporting member 3 onto one surface of the frame 2 and securing thereto. At this time, as illustrated in FIG. 1B, the adhesive surface 3a of the supporting member 3 is opposed to the frame. Next, the second layer 12 of the substrate 1 is attached to the adhesive surface 3a of the supporting member 3, thereby to allow the substrate 1 to be held on the conveying carrier 10.

### (Placement Process)

Next, the conveying carrier 10 holding the substrate 1 is placed on a stage provided in a vacuum chamber, which is a processing chamber of a plasma processing apparatus 100.

As illustrated in FIG. 2, the plasma processing apparatus 100 includes a stage 111. The conveying carrier 10 is set on the stage 111, with the surface holding the substrate 1 of the supporting member 3 faced upward. The stage 111 has such a size that the whole conveying carrier 10 can be seated thereon. Above the stage 111, a cover 124 covering the frame 2 and at least part of the supporting member 3 and having a window 124W for exposing at least part of the substrate 1 therefrom is arranged. The cover 124 is provided with pressure members 107 for pressing the frame 2 downward while the frame 2 is on the stage 111. The pressure members 107 are preferably a member that can achieve point contact with the frame 2 (e.g., a coil spring or an elastic resin having elasticity). This can correct a distortion of the frame 2, while restricting a thermal communication between the frame 2 and the cover 124.

The stage 111 and the cover 124 are arranged in a vacuum chamber 103 which is a processing chamber. The vacuum chamber 103 is approximately cylindrical with the top open. The open top is closed by a dielectric member 108 serving as a lid. Examples of the constituent material of the vacuum chamber 103 include aluminum, stainless steel (SUS), and aluminum with anodic oxide coating. Examples of the constituent material of the dielectric member 108 include yttrium oxide (Y₂O₃), aluminum nitride (AlN), alumina (Al₂O₃), quartz (SiO₂), and other dielectric materials. Above the dielectric member 108, a first electrode 109 serving as an upper electrode is arranged. The first electrode 109 is, for example, a coil when the plasma processing apparatus 100 includes an inductively coupled-type plasma source. The first electrode 109 is electrically connected to a first high-frequency power source 110A. The stage 111 is disposed on the bottom side in the vacuum chamber 103.

The vacuum chamber 103 is provided with a gas inlet 103a and a gas outlet 103b. The gas inlet 103a is connected to plasma-generating gas supply sources, i.e., a processing gas source 112 and an ashing gas source 113, each through a conduit. The gas outlet 103b is connected to a decompression system 114 including a vacuum pump for exhausting the gas within the vacuum chamber 103, to reduce the pressure therein. While the vacuum chamber 103 is supplied with a processing gas, the first electrode 109 is applied with a high-frequency power from the first high-frequency power source 110A. This generates a plasma in the vacuum chamber 103.

The stage 111 includes an electrode layer 115, a metal layer 116, and a base table 117 supporting the electrode layer 115 and the metal layer 116, each being approximately circular. The stage 111 further includes a peripheral member 118 surrounding the electrode layer 115, the metal layer 116, and the base table 117. The peripheral member 118 is formed of a metal having electrical conductivity and etching resistance, and serves to protect the electrode layer 115, the metal layer 116, and the base table 117 from plasma exposure. On the top surface of the peripheral member 118, an annular circumferential ring 129 is disposed. The circumferential ring 129 serves to protect the top surface of the peripheral member 118 from plasma exposure. The electrode layer 115 and the circumferential ring 129 are formed of, for example, the dielectric material as mentioned above.

Within the electrode layer 115, an electrode for electrostatic chucking (hereinafter, ESC electrode 119), and a second electrode 120 electrically connected to a second high-frequency power source 110B are disposed. By applying a high-frequency power from the second high-frequency power source 110B to the second electrode 120, the incident energy when the ions in the plasma generated in the vacuum chamber 103 collide with the substrate placed on the stage can be controlled. The ESC electrode 119 is electrically connected to a DC power source 126. The ESC electrode 119 and the DC power source 126 constitute an electrostatic chuck system. The electrostatic chuck system pulls the supporting member 3 onto the stage 111 and secures it thereto. Although a description will be given below of a case where the electrostatic chuck system is used as a securing system for securing the supporting member 3 to the stage 111, this should not be taken as a limitation. A clamp (not shown) may be used for securing the supporting member 3 to the stage 111.

The metal layer 116 is formed of, for example, aluminum with an anodic oxidation coating. The metal layer 116 has a coolant channel 127 formed therein. The coolant channel 127 is configured to cool the stage 111. By cooling the stage 111, the supporting member 3 set on the stage 111 is cooled down, and the cover 124 partially in contact with the stage 111 is also cooled down. This protects the substrate 1 and the supporting member 3 from being damaged by being heated during plasma processing. A coolant in the coolant channel 127 is circulated by a coolant circulator 125.

Around the peripheral portion of the stage 111, a plurality of supporting rods 122 extending through the stage 111 are disposed. The supporting rods 122 support the frame 2 of the conveying carrier 10. The supporting rods 122 are driven by a lifting system 123A, and move upward and downward. The conveying carrier 10 having delivered into the vacuum chamber 103 is passed onto the supporting rods 122 at a predetermined raised position. Then the supporting rods 122 descend until their top surfaces become flush with or lower than the top surface of the stage 111, which sets the conveying carrier 10 at a predetermined position on the stage 111.

A plurality of lifting rods 121 are coupled to the peripheral edge of the cover 124, to lift and lower the cover 124. The lifting rods 121 are driven by a lifting system 123B. The lifting and lowering operation of the cover 124 by the lifting systems 123B can be controlled independently from the operation by the lifting system 123A.

A controller 128 controls operations of component elements of the plasma processing apparatus 100 including the first high-frequency power source 110A, the second high-frequency power source 110B, the processing gas source 112, the ashing gas source 113, the decompression system 114, the coolant circulator 125, the lifting systems 123A and 123B, and the electrostatic chuck system.

When placing the conveying carrier 10 on the stage 111, within the vacuum chamber 103, the cover 124 is lifted to a predetermined position by means of the lifting rods 121. A gate valve (not shown) opens to allow the conveying carrier 10 to be delivered. The supporting rods 122 are on standby at a raised position. When the conveying carrier 10 reaches a predetermined position above the stage 111, the conveying carrier 10 is passed onto the supporting rods 122. The conveying carrier 10 is placed onto the supporting rods 122, with the adhesive surface 3a of the supporting member 3 faced upward.

After the conveying carrier 10 is passed onto the supporting rods 122, the vacuum chamber 103 is closed in a hermetically sealed state. Next, the supporting rods 122 start descending. When the supporting rods 122 have descended until their top surfaces become flush with or lower than the top surface of the stage 111, the conveying carrier 10 is set on the stage 111. Then, the lifting rods 121 are driven to lower the cover 124 to a predetermined position. The distance between the cover 124 and the stage 111 is adjusted so that the pressure members 107 in the cover 124 each come in point-contact with the frame 2. In this way, the frame 2 is pressed downward by the pressure members 107, and the frame 2 and a portion not holding the substrate 1 of the supporting member 3 are covered with the cover 124, and thus, the substrate 1 is exposed from the window 124W. The pressure members 107 are preferably a member that can achieve point contact with the frame 2 (e.g., a coil spring or an elastic resin having elasticity). This can correct a distortion of the frame 2, while restricting a thermal communication between the frame 2 and the cover 124.

The cover 124 is, for example, doughnut-shaped having an approximately circular contour, and has a constant width and thin thickness. The inner diameter of the cover 124 (i.e., the diameter of the window 124W) is smaller than that of the frame 2, and the outer diameter of the cover 124 is greater than the outer diameter of the frame 2. Therefore, when the cover 124 is lowered while the conveying carrier 10 is seated on the stage at a predetermined position, the cover 124 can cover the frame 2 and at least part of the supporting member 3. From the window 124W, the substrate 1 is at least partially exposed. The cover 124 is constituted of, for example, a dielectric such as ceramics (e.g., alumina, aluminum nitride) or quarts, or a metal, such as aluminum or aluminum with an anodic oxidation coating. The pressure members 107 can be constituted of the aforementioned dielectric or metal, or a resin material.

After the conveying carrier 10 is passed onto the supporting rods 122, a voltage is applied to the ESC electrode 119 from the DC power source 126. The supporting member 3 comes in contact with the stage 111 and, simultaneously, the supporting member 3 is electrostatically chucked to the stage 111. The voltage application to the ESC electrode 119 may be initiated after the supporting member 3 is placed on (or comes in contact with) the stage 111.

### (Individualization Process)

In the individualization process, the processes (i) (protective film formation process), (ii) (protective film removal process), and (iii) (semiconductor layer removal process) are sequentially repeated as one cycle.

### (Protective Film Formation Process)

The first plasma used in the process (i) (protective film formation process) can be generated from, for example, a gas containing fluorine and carbon (first etching gas). The gas containing fluorine and carbon (first etching gas) is, for example, a gas containing C₄F₈, CH₂F₂, or CHF₃.

By using the first plasma generated from the gas containing fluorine and carbon, a protective film containing fluorinated carbon can be formed on the surface of the substrate including the sidewall and the bottom of the groove. At this time, upon application of power to the second electrode 120, a bias potential is generated between the stage and the plasma, and the ions in the plasma are accelerated by the bias potential toward the substrate placed on the stage, and collide therewith. The collision generates energy, which removes the reaction product that has been produced in the process (iii) (semiconductor layer removal process) in the previous cycle, and has accumulated on the sidewall of the upper portion of the groove and narrowed the opening.

The protective film formation process is carried out, for example, under the following conditions: while supplying C₄F₈ as a raw material gas at a rate of 150 to 600 sccm, the pressure in the processing chamber is controlled to 1 to 25 Pa, with the power applied to the first electrode 109 from the first high-frequency power source 110A set at 1500 to 5000 W, and the power applied to the second electrode 120 from the second high-frequency power source 110B set at 5 to 150 W; and the processing time is 0.1 to 10 seconds.

The following is a specific example of the conditions for generating the first plasma in the process (i).

First etching gas: C₄F₈ gas

Flow rate: 300 sccm

Total pressure: 5.0 Pa

Power applied to first electrode: 2000 W

Power applied to second electrode: 50 W

Processing time: 1 s

The process (i) (protective film formation process) includes a first step and a second step following the first step, in which the high-frequency power applied to the stage in the first step may be set larger than the high-frequency power applied to the stage in the second step. In the first step, the application of a larger high-frequency power can efficiently remove the reaction product that has been produced in the process (iii) (semiconductor layer removal process) in the previous cycle and has attached to and accumulated on the sidewall. In the second step, with the reaction product removed, a protective film is formed on the sidewall of the groove. In the second step, a high-frequency power smaller than that in the first step is applied to the stage, and the first plasma is more likely to collide with the sidewall as well as the bottom of the groove. Therefore, a protective film can be easily formed uniformly on the sidewall of the groove.

In the first step, the high-frequency power applied to the stage is, for example, 25 to 100 W, and may be 25 W or more, 50 W or more, or 75 W or more. On the other hand, in the second step, the high-frequency power applied to the stage can be, for example, 0 to 20 W. In the second step, no high-frequency power may be applied to the stage.

The high-frequency power applied to the stage in the process (i) (protective film formation step) (when the process (i) includes the first step and the second step, it refers to the high-frequency power applied to the stage in the first step, and the same applies hereinafter), may be increased continuously or stepwise with increase in the depth of the groove formed in the compound semiconductor layer. That is, the high-frequency power applied to the stage in the process (i) may be changed according to the executed number of cycles of the processes (i) to (iii), such that the high-frequency power is increased continuously or stepwise with increase in the executed number of cycles.

When the executed number of cycles is small, and the depth of the groove formed in the compound semiconductor layer is small, and the reaction product produced in the process (iii) is easily exhausted outside the groove. Therefore, the high-frequency power applied to the stage may be small. On the other hand, as the executed number of cycles increases, and the depth of the groove formed in the compound semiconductor layer increases, the reaction product produced in the process (iii) is likely to remain in the groove, and tends to attach to the sidewall of the groove and accumulate thereon. Therefore, in order to remove the reaction product attached to and accumulated on the sidewall of the groove, it is preferable to apply a higher high-frequency power to the stage.

The high-frequency power applied to the stage in the process (i) may be changed stepwise according to the depth of the groove formed in the compound semiconductor layer. For example, the high-frequency power applied to the stage in the process (i) may be changed in relation to the groove depth, to be 25 W or more when the groove depth is 40 μm or more, 50 W or more when the groove depth is 70 μm or more, and 75 W or more when the groove depth is 100 μm or more.

### (Protective Film Removal Process)

The second plasma used in the process (ii) (protective film removal process) can be generated from, for example, a gas containing at least one of chlorine and bromine (second etching gas). The second etching gas may contain only one of chlorine and bromine, or may contain both of them. The gas species included in the second etching gas may be, for example, at least one selected from the group consisting of HCl, Cl₂, BCl₃, SiCl₄, HBr, Br₂, BBr₃, and SiBr₄. The second etching gas may be one of these gas species, or may be a mixed gas of two or more of these species.

The protective film removal process is carried out, for example, under the following conditions: while supplying a mixed gas of BCl₃, Cl₂, and Ar as a raw material gas at a rate of 100 to 450 sccm, the pressure in the processing chamber is controlled to 1 to 15 Pa, with the power applied to the first electrode 109 from the first high-frequency power source 110A set at 1000 to 5000 W, the power applied to the second electrode 120 from the second high-frequency power source 110B set at 50 to 400 W; and the processing time is 3 to 12 seconds.

The following is a specific example of the conditions for generating the second plasma in the process (ii).

Second etching gas: mixed gas of BCl₃, Cl₂, and Ar

Total flow rate: 190 sccm

BCl₃ flow rate: 70 sccm

Cl₂ flow rate: 60 sccm

Ar flow rate: 60 sccm

Total pressure: 3.0 Pa

Power applied to first electrode: 1500 W

Power applied to second electrode: 200 W

Processing time: 6 s

### (Semiconductor Layer Removal Process)

The third plasma used in the process (iii) can be generated from a gas containing at least one of chlorine and bromine (third etching gas). The third etching gas may contain only one of chlorine and bromine, or may contain both of them. The gas species included in the third etching gas may be, for example, at least one selected from the group consisting of HCl, Cl₂, BCl₃, SiCl₄, HBr, Br₂, BBr₃, and SiBr₄. The third etching gas may be one of these gas species, or may be a mixed gas of two or more of these species.

The third etching gas may include the same gas species as those included in the second etching gas. The third etching gas may be composed of a combination of the gas species same as those in the second etching gas, but differing in the mixing ratio (and/or partial pressure ratio) from that in the second etching gas.

The semiconductor layer removal process is carried out, for example, under the following conditions: while supplying a mixed gas of BCl₃, Cl₂, and Ar as a raw material gas at a rate of 200 to 800 sccm, the pressure in the processing chamber is controlled to 1 to 20 Pa, with the power applied to the first electrode 109 from the first high-frequency power source 110A set at 1000 to 5000 W, the power applied to the second electrode 120 from the second high-frequency power source 110B set at 20 to 400 W; and the processing time is 5 to 30 seconds.

The following is a specific example of the conditions for generating the third plasma in the process (iii).

Third etching gas: mixed gas of BCl₃, Cl₂, and Ar

Total flow rate: 380 sccm

BCl₃ flow rate: 70 sccm

Cl₂ flow rate: 290 sccm

Ar flow rate: 20 sccm

Total pressure: 5.0 Pa

Power applied to first electrode: 2000 W

Power applied to second electrode: 50 W

Processing time: 15 s

An inert gas, such as Ar, may be added to the first etching gas, the second etching gas, and the third etching gas, if necessary.

### (Compound Semiconductor Layer)

The compound semiconductor constituting the compound semiconductor layer is a semiconductor material containing at least two different elements. Examples of the compound semiconductor include: III-V semiconductors, such as GaAs, AlGaAs, AlAs, InP, GaP, and GaN; II-VI semiconductors, such as CdTe and ZnSe; and IV-IV semiconductors containing a plurality of Group IV elements, such as SiC. These compound semiconductors, when etched, produce a product lower in volatility than that silicon and silicon oxide produce, and are therefore called difficult-to-etch materials. The method of the present embodiment can be suitably used for forming a groove in these difficult-to-etch materials.

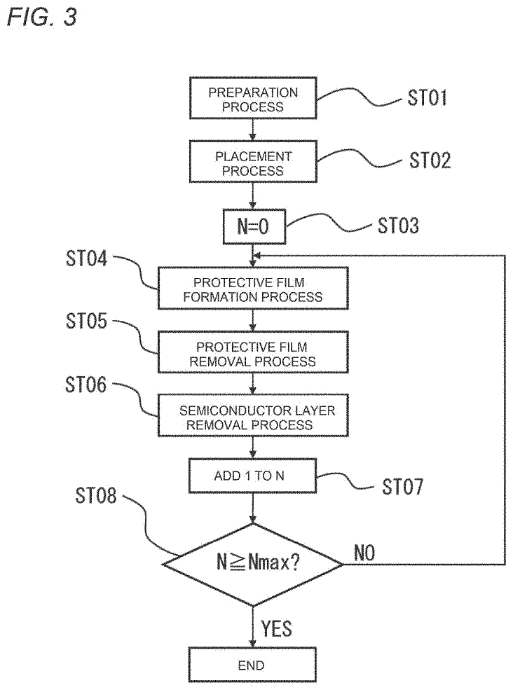

FIG. 3 is an exemplary flowchart of an element chip manufacturing method (plasma processing method) according to the present embodiment. In the example of FIG. 3, a substrate having a compound semiconductor layer and a mask is prepared first (ST01). The substrate includes a plurality of element regions and a dividing region defining the element regions. The mask covers the compound layer in the element regions. On the other hand, in the dividing region, the compound semiconductor layer is exposed from the mask, forming an opening along the dividing region.

Next, the substrate is placed, while being held by the supporting member, on a stage provided in the processing chamber of the plasma processing apparatus (ST02).

Subsequently, individualization is performed to divide the substrate into a plurality of element chip having the element regions. The individualization is carried out by repeating a protective film formation process ST04, a protective film removal process ST05, and a semiconductor layer removal process ST06, as one cycle. The protective film formation process ST04, the protective film removal process ST05, and the semiconductor layer removal process ST06 correspond to the above-mentioned processes (i) to (iii), respectively, and detailed description thereof will be omitted.

After the placement process ST02 and before the initial protective film formation process ST04, the executed number N of cycles for individualization is set to 0 (ST03). The executed number N of cycles is increased by one after the semiconductor layer removal process ST06 is completed (ST07).

The executed number N of cycles reflects the depth of the groove formed in the compound semiconductor layer. When N reaches the predetermined maximum executed number of cycles Nₘₐₓ or greater, it is assumed that a groove having a predetermined depth is formed in the compound semiconductor layer, and the process is terminated (a “YES” branch in ST08). On the other hand, when N is less than Nₘₐₓ, the process returns to ST04 and repeats the cycle consisting of the protective film formation process ST04, the protective film removal process ST05, and the semiconductor layer removal process ST06 (a “NO” branch in ST08).

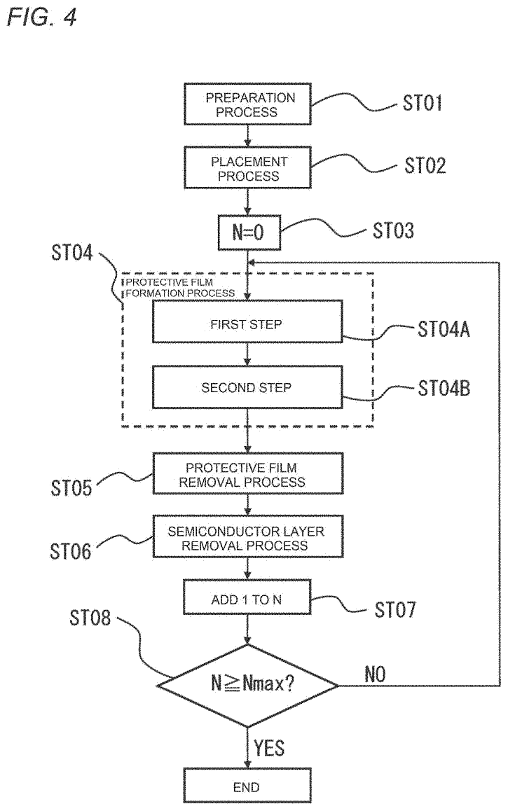

FIG. 4 is another exemplary flowchart of an element chip manufacturing method (plasma processing method) according to the present embodiment. In the example of FIG. 4, the protective film formation process ST04 includes a first step ST04A and a second step ST04B. The high-frequency power applied to the stage in the first step ST04A is higher than that in the second step ST04B.

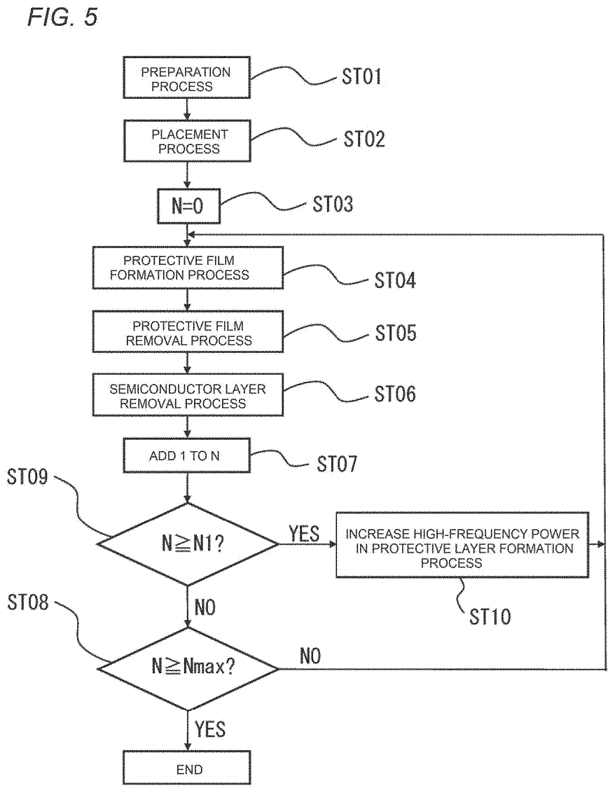

FIG. 5 is yet another exemplary flowchart of an element chip manufacturing method (plasma processing method) according to the present embodiment. In the example of FIG. 5, a determination is made as to whether the executed number N of cycles is equal to or greater than a predetermined value N1 (N1<Nₘₐₓ) (ST09), and when N=N1, a process (ST10) is performed to change the conditions for plasma processing in the subsequent protective film formation process ST04 and increase the setting value of the high-frequency power applied to the stage in the protective film formation process ST04. Subsequent to this process, in the protective film formation process, the plasma processing is performed at the changed value of high-frequency power. In this way, the high-frequency power applied to the stage in the protective film formation process is increased when the depth of the groove in the compound semiconductor layer is equal to or greater than the predetermined depth corresponding to N1, so that the reaction product attached to the sidewall of the groove can be easily removed. It is therefore possible to efficiently remove the reaction product that otherwise becomes difficult to remove as the groove is deepened.

The present invention will be specifically described below with reference to Examples and Comparative Examples. The present invention is, however, not limited to the Examples.

### Example 1

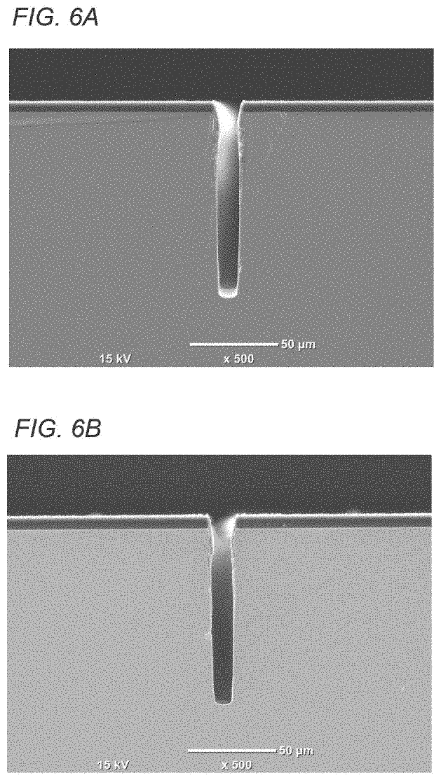

A GaAs substrate was plasma-etched under the conditions shown in Table 1, thereby to form a deep groove. FIG. 6A is an SEM photograph of a cross section of the substrate across the element regions. The results of dimension measurement showed that the groove depth was 104.7 μm. The opening width at the top of the groove was 16.7 μm, the groove width at a depth of 40 μm from the surface was 14.6 μm, and the groove width at the bottom was 10.7 μm. Although the groove width at the bottom was reduced from the opening width, the ratio of the reduced amount to the opening width was suppressed to 36%.

### Comparative Example 1

Except for applying no high-frequency power to the stage in the protective film formation process, a GaAs substrate was plasma-etched under the same conditions as in Example 1, thereby to form a deep groove. FIG. 6B shows an SEM photograph of a cross section of the substrate across the element regions. The results of dimension measurement showed that the groove depth was 99.3 μm. The opening width at the top of the groove was 17.2 μm, the groove width at a depth of 40 μm from the surface was 13.5 μm, and the groove width at the bottom was 9.6 μm. The groove width at the bottom was reduced from the opening width, and the ratio of the reduced amount to the opening width was as high as 45%.

TABLE 1

| | | Ex. 1 | Com. Ex. 1 |
|---|---|---|---|
| Protective film | Gas flow rate | C₄F₈ | 300 sccm |
| formation process | Pressure | 5.0 Pa | |
| | Power applied to first electrode | 2000 W | |
| | Power applied to second elec- | 50 W | 0 W |
| | trode | | |
| | Processing time | 1 s | |
| Protective film | Gas flow rate | BCl₃ | 70 sccm |
| removal process | | Cl₂ | 60 sccm |
| | | Ar | 60 sccm |
| | Pressure | 3.0 Pa | |
| | Power applied to first electrode | 1500 W | |
| | Power applied to second elec- | 200 W | |
| | trode | | |
| | Processing time | 6 s | |
| Semiconductor layer | Gas flow rate | BCl₃ | 70 sccm |
| removal process | | Cl₂ | 290 sccm |
| | | Ar | 20 sccm |

| | | |
|---|---|---|
| | Pressure | 5.0 Pa |
| | Power applied to first electrode | 2000 W |
| | Power applied to second elec- | 50 W |
| | trode | |
| | Processing time | 15 s |
| Number of cycles | | 30 |

### INDUSTRIAL APPLICABILITY

The plasma processing method according to the present invention is applicable to an etching process for forming a deep groove in a compound semiconductor layer, and particularly suitably applicable to a method for manufacturing element chips by dicing a compound semiconductor substrate.

### REFERENCE NUMERALS

1: substrate
1X: first principal surface
1Y: second principal surface
11: first layer
12: second layer
10: conveying carrier
2: frame
2a: notch
2b: corner cut
3: supporting member
3a: adhesive surface
3b: non-adhesive surface
100: plasma processing apparatus
103: vacuum chamber
103a: gas inlet
103b: gas outlet
107: pressure member
108: dielectric member
109: first electrode
110A: first high-frequency power source
110B: second high-frequency power source
111: stage
112: processing gas source
113: ashing gas source
114: decompression system
115: electrode layer
116: metal layer
117: base table
118: peripheral member
119: ESC electrode
120: second electrode
121: lifting rod
122: supporting rod
123A, 123B: lifting system
124: cover
124W: window
125: coolant circulator
126: DC power supply
127: coolant channel
128: controller
129: circumferential ring

What is claimed is:

1. An element chip manufacturing method, comprising:
a preparation process of preparing a substrate having a compound semiconductor layer and a mask, the compound semiconductor layer including a plurality of element regions and a dividing region defining the element regions, the mask covering the compound semiconductor layer in the element regions and exposing the compound semiconductor layer in the dividing region;
a placement process of placing the substrate on a stage provided in a processing chamber of a plasma processing apparatus; and
an individualization process of forming a groove corresponding to the dividing region in the compound semiconductor layer, with a plasma generated inside the processing chamber, and then dividing the substrate into a plurality of element chips having the element regions, wherein
in the individualization process,
a first process of forming a protective film at least on a bottom of the groove, with a first plasma generated inside the processing chamber,
a second process of removing the protective film at the bottom, with a second plasma generated inside the processing chamber, to expose the compound semiconductor layer, and
a third process of removing the conductive semiconductor layer exposed at the bottom of the groove, with a third plasma generated inside the processing chamber from a gas containing at least one of chlorine and bromine, while allowing a reaction product between the compound semiconductor layer and the third plasma to accumulate on an upper portion of the groove
are sequentially repeated, and
in the first process, the reaction product accumulated on the upper portion of the groove is removed by applying a high-frequency power to the stage.

2. The element chip manufacturing method according to claim 1, wherein the first plasma is generated from a gas containing fluorine and carbon.

3. The element chip manufacturing method according to claim 1, wherein the second plasma is generated from a gas containing at least one of chlorine and bromine.

4. The element chip manufacturing method according to claim 1, wherein
the first process includes a first step and a second step following the first step, and
the high-frequency power applied to the stage in the first step is larger than the high-frequency power applied to the stage in the second step.

5. The element chip manufacturing method according to claim 1, wherein the high-frequency power applied to the stage in the first process is increased continuously or stepwise with increase in depth of the groove formed in the compound semiconductor layer.

6. A plasma processing method, comprising:
a preparation process of preparing a substrate having a compound semiconductor layer and a mask partially covering a surface of the compound semiconductor layer;
a placement process of placing the substrate on a stage provided in a processing chamber of a plasma processing apparatus; and
a process of forming a groove in the compound semiconductor layer in a region where the compound semiconductor layer is not covered with the mask, wherein
in the process of forming a groove,
a first process of forming a protective film at least on a bottom of the groove by exposing the substrate to a first plasma,
a second process of removing the protective film at the bottom by exposing the substrate to a second plasma, to expose the compound semiconductor layer, and
a third step of removing the compound semiconductor layer exposed at the bottom of the groove by exposing the substrate to a third plasma generated from a gas containing at least one of chlorine and bromine, while allowing a reaction product between the compound semiconductor layer and the third plasma to accumulate on an upper portion of the groove
are sequentially repeated, and
in the first process, the reaction product accumulated on the upper portion of the groove is removed by applying a high-frequency power to the stage.
